(19) United States
(12) Patent Application Publication
(10) Pub. No.: US 2005/0210358 A1
(43) Pub. Date: Sep. 22, 2005

(54) Soft decoding of linear block codes

(75) Inventors: Antoine Chouly, Paris (FR); Olivier Pothier, Paris (FR); Mylene Pischela, Paris (FR)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILLIPS ELECTRONICS N.V.

(21) Appl. No.: 10/515,741

(22) PCT Filed: May 15, 2003
(86) PCT No.: PCT/IB03/02075

§ 371 Date: Nov. 24, 2004

(30) Foreign Application Priority Data
May 31, 2002 (EP) 02291342.0

(51) Int. Cl. H03M 13/00

(52) U.S. Cl. 714/753

(57) ABSTRACT

The invention relates to digital transmission and recording systems. It particularly relates to a receiver for receiving a sequence of encoded data produced by a data source from an information sequence and encoded by an encoder, the received encoded data sequence possibly comprising errors, the receiver comprising decoding means for retrieving the information sequence from the received encoded data sequence. The decoding means comprises:—first soft-input decoding means using a first error correction algorithm for producing a first set of at least one candidate corresponding to a first selection of possible information sequence produced by the data source,—second soft-input decoding means using a second error correction algorithm for producing a second set of at least one candidate corresponding to a second selection of possible information sequence produced by the data source,—selection means for selecting, among the first and second set of candidates, the most reliable candidate with respect to a predetermined criterion.

### FIELD OF THE INVENTION

The invention generally relates to digital transmission and recording systems. In particular, it relates to a receiver for receiving a sequence of encoded data produced by a data source from an information sequence and encoded by an encoder, the received encoded data sequence possibly comprising errors, the receiver comprising decoding means for retrieving the information sequence from the received encoded data sequence.

The invention also relates to a method of receiving a sequence of encoded data produced by a data source from an information sequence and to a computer program product for carrying out the method.

It also relates to an optical storage medium and to a transmission or recording system.

The invention applies particularly to broadcasting systems for digital television compatible with e.g. the DVB (Digital Video Broadcasting) standards, to storage systems, such as e.g. Digital Audio Disc and DVD (Digital Video Disc), to xDSL (Digital Subscriber Line) and return channels (via satellite, cable or terrestrial).

### BACKGROUND ART

Digital transmission or recording systems require efficient error correcting techniques in order to cope with errors introduced by transmission or storage channels. Among these techniques, linear block codes, and especially Reed-Solomon codes have a prominent importance, because they are widely used in many different types of digital communication systems, often concatenated with an internal convolutional code. Most applications use a hard input, hard output algebraic decoder, such as the Berlekamp-Massey algorithm for Reed-Solomon codes. However, the loss of information implied by hard input decoding leads to a lack of efficiency for algebraic decoders. Moreover, more optimal decoding techniques i.e. maximum likelihood decoding are too complex to be implemented for long and practical codes. Consequently, sub optimal soft decision (SD) decoding techniques have been investigated. One of these techniques, called reliability-based decoding (RBD) includes algorithms based on the ordering of received symbols in accordance with their reliability values.

### OBJECT AND SUMMARY OF THE INVENTION

It is an object of the invention to provide a receiver using a new RBD method, which strikes a balance between complexity and error performance for a fixed Signal to Noise ratio (SNR).

According to the invention, a receiver is provided for receiving a sequence of data encoded by a linear block code and produced by a data source from an information sequence, the received encoded data sequence possibly comprising errors, the receiver comprising decoding means for retrieving the information sequence from the received encoded data sequence, the decoding means comprising:
first soft-input decoding means using a first error correction algorithm for producing a first set of at least one candidate corresponding to a first selection of possible information sequence produced by the data source,
second soft-input decoding means using a second error correction algorithm for producing a second set of at least one candidate corresponding to a second selection of possible information sequence produced by the data source,
selection means for selecting, among the first and second set of candidates, the most reliable candidate with respect to a predetermined criterion.

A soft-input, soft-output (SISO) version of the invention is also described.

The invention applies to any linear block code (binary or non-binary) for which an algebraic decoder is available, and particularly to Reed-Solomon codes. It also applies to systems with a linear block code concatenated with an internal convolutional code if the convolutional code is decoded using a soft output decoder, e.g. Soft Output Viterbi Algorithm or SOVA.

### BRIEF DESCRIPTION OF THE DRAWINGS

The invention and additional features, which may be optionally used to implement the invention to advantage, are apparent from and will be elucidated with reference to the drawings described hereinafter.

FIG. 1 is a conceptual block diagram illustrating an example of a system comprising a receiver according to the invention,

FIG. 2 is a schematic showing an example of an optical storage system according to the invention.

### DETAILED DESCRIPTION OF THE DRAWINGS

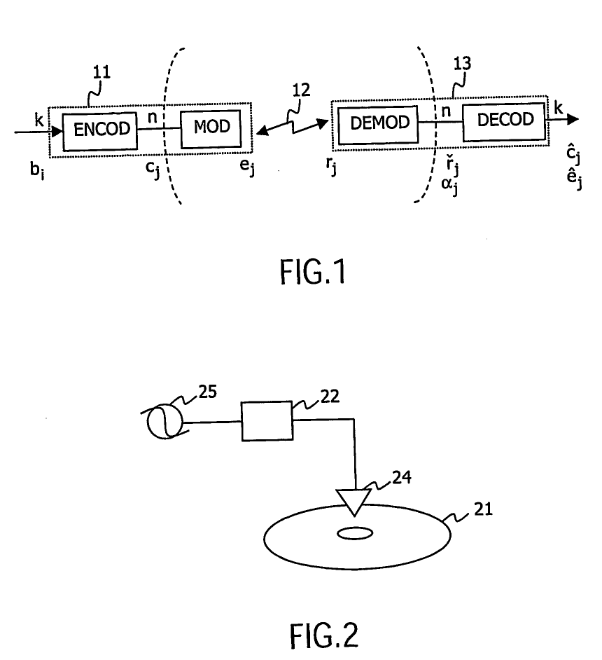

FIG. 1 shows a transmission system in accordance with the invention. The invention also applies to an optical storage system, wherein a receiver or optical reader is adapted to receive and read digital data stored on an optical storage medium or Disc e.g. a Digital Audio Disc, A Digital Video Disc, etc. An optical system in accordance with the invention is illustrated in FIG. 2.

The transmission system of FIG. 1 comprises a transmitter 11, a physical transmission channel 12 and a receiver 13. The transmitter comprises an encoder ENCOD and a modulator MOD. The transmission channel 12 can use terrestrial (hertzian), radio, cable or satellite links. The receiver comprises a demodulator DEMOD and a decoder DECOD. The encoder and the decoder are symmetrical and compatible with each other for encoding and decoding the same linear block code, such as, for example, a Reed-Solomon code. For the decoder, the channel consists of the blocks between brackets, that is, the modulator, the physical channel 12 and the demodulator. The invention is not limited to Reed-Solomon codes and applies to any linear binary or non-binary block code, for which an algebraic decoding is available. The aim of such coding is to enable the system to cope with transmission errors. To perform error correction, the encoder outputs an encoded data sequence, which is longer than the input data sequence comprising information data, by adding parity or redundancy data to the information data sequence received at the input of the encoder. The code is denoted C(n,k), n being the length of the code, which corresponds to the number of symbols or data of the output sequence produced by the encoder, k being the number of information data in the data sequence at the input of the encoder. In the case of a binary linear code, k and n are the number of information and coded bits, respectively.

At the receiver side, the demodulator DEMOD outputs a sequence of n data or symbols received from the channel and possibly comprising transmission errors and a sequence of n reliability values associated with the sequence of n data or symbols, for the decoder DECOD to decode the sequence, correct the errors and retrieve the originals transmitted sequence of k information data or symbols. To this end, the decoder DECOD comprises:
first decoding means using a first error correction algorithm for producing a first set of at least one candidate corresponding to a first selection of possible information sequence produced by the data source, i.e. at the input of the encoder here,
second decoding means using a second error correction algorithm for producing a second set of at least one candidate corresponding to a second selection of possible information sequence produced by the data source,
selection means for selecting, among the first and second set of candidates, the most reliable candidate with respect to a predetermined criterion.

In a preferred embodiment of the invention:
the first error correction algorithm is a variant of the so-called Chase algorithm, described e.g. in the article by D. Chase: “A class of algorithms for decoding block codes with channel measurement information” published in IEEE Transaction on Information Theory, vol IT-18, pages 170-182, January 1972, denoted [1]
the second error correction algorithm is an extension of a variant of the so-called Fossorier-Lin algorithm, described e.g. In the article by M. P. C. Fossorier and S. Lin: “soft-decision decoding of linear block codes based on ordered statistics, published in IEEE Transactions on Information Theory, vol 41, pages 1379-1396, September 1995, denoted [2] and
the predetermined criterion is based on the Euclidian distance between the received data and the candidates from the first and second set of candidates, the most reliable candidate being the candidate, for which said distance with the received data is minimum.

The preferred embodiment based on a combination of Chase and low-order Fossorier-Lin algorithm, which applies not only to binary linear block codes but also to any linear block code, allows a better error performance to be archieved for a fixed Signal-to-Noise Ratio (SNR) than a Fossorier-Lin algorithm of higher order, which only applies to binary codes and which is far more complex.

The invention extends the Fossorier-Lin principle to non-binary block codes over the Galois Field GF(2^{m}) by describing the latter as binary codes using a binary representation of the field elements. A non-binary code denoted C(n,k) over GF(2^{m}) is described as a binary code denoted C_{bin}(n×m,k×m). Chase and Fossorier-Lin algorithms use channel measurement information or reliabilities in complementary ways. They both produce a set of codewords or candidates, among which the candidate which fulfills the same predetermined criterion, that is to say which minimizes the Euclidian distance to the received real sequence, is selected. Chase algorithm assumes that the hard-decision received sequence is more likely to be wrong on the least reliable bits, and therefore complements them before decoding them with an algebraic decoder, such as the Berlekamp-Massey decoder for Reed-Solomon codes described in [1]. On the other hand, Fossorier-Lin algorithm assumes that the most reliable bits are correct and re-calculates the other bits from the most reliable ones. The invention reveals and exploits the complements of Chase and Fossorier-Lin algorithms. If one algorithm fails to produce the right codeword, the other one is very likely to find it because they have different limitations. Chase fails if more than a predetermined number of errors are located outside the least reliable positions to be complemented, whereas order-i Fossorier-Lin falls if there are more than i errors among the most reliable bits. In the preferred embodiment, the order of reprocessing Fossorier-Lin is limited to i=1 or i=2.

To explain the invention in more details, let us express the data with binary elements or bits. In the case of a non-binary linear code, the number of bits per symbol or data is denoted m. In the case of a binary linear code, m is equal to 1. N=n×m is the length of the code in number of bits. K=k×m is the dimension of the code in number of bits. The cardinal number of symbols in the alphabet of the code is equal to 2^{m}. We denote:
b=(b₁, . . . , b_{K}): the data at the input of the encoder ENCOD,
c=(c₁, . . . c_{N}): the data at the output of the encoder,
e=(e₁ . . . , e_{N}): the output of the modulator MOD,
r=(r₁, . . . , r_{N}): the data (belonging to the real space) received by the receiver at the input of the demodulator DEMOD,
\check{r}=(\check{r}₁, . . . , \check{r}_{N}) and α=(α₁, . . . , α_{N}): the soft-output decision of the demodulator, \check{r}ⱼ with j=1, . . . N being the decisions on the received data bits and αⱼ being the reliabilities of the decided bits, and
ĉ=(ĉ₁, . . . , ĉ_{N}): the output of the decoder DECOD, which corresponds to an estimate of the encoded data produced by the encoder at the transmitter side,
ê=(ê₁, . . . , ĉ_{N}): another expression of the output of the decoder DECOD, which corresponds to an estimate of the modulated data produced by the modulator MOD.

The first decoding means of the decoder receives the soft-output decisions \check{r}ⱼ and αⱼ from the demodulator. It sorts the \check{r}ⱼ with respect to their associated reliabilities (αⱼ. In accordance with the preferred embodiment using as first decoding means a variant of the Chase algorithm, it sorts the \check{r}ⱼ so that the new sorted \check{r}ⱼ and αⱼ denoted \check{r}′ⱼ and α′ⱼ, respectively, are such that α′ⱼ<α′ⱼ₊₁. 2^{t} Intermediate candidates are then built from \check{r}, t being lower or equal to the error correction capacity of the algebraic decoder, by changing one of the t least reliable bits for each intermediate candidate (the t least reliable bits being the first t bits in accordance with the preferred embodiment). Then an algebraic decoding such as e.g. the Berlekamp-Massey is performed on the intermediate candidates, possibly after inverse permutation to put the bits in their original order, for producing a first set of 2^{t} candidates. The method consists of changing at least one bit in part of the least reliable bits to form a set of intermediate candidates and to apply an algebraic decoding to the intermediate candidates to generate the first set of candidates corresponding to possibly transmitted encoded symbols. The processing can be summarized with the following four steps:
sort the N reliabilities of the bits of the soft-output decision of the demodulator,
generate 2^{t} patterns or intermediate candidates with 1's located at the positions to be inverted, which depends on the Chase algorithm [1],
reshape the bits into symbols or data to process with the algebraic decoding in order to generate 2^{t} codeword estimates, which is the first set of candidates,
if algebraic decoding succeeds, possibly compute Euclidian distance from the obtained modulated codewords or candidates to the received real sequence.

The following description relates to the second decoding means in the case where the used code is binary, the second decoding means of the decoder also receives the \check{r}ⱼ and the αⱼ from the demodulator. It also sorts the \check{r}ⱼ with respect to their associated reliabilities αⱼ. The aim is to re-calculate the least reliable bits from more reliable bits using a second error correction algorithm such as e.g. the Fossorier-Lin algorithm. As a matter of fact, linear block codes (which are linear sub-space) are defined so that for a given codeword, any subset of n-k bits can be computed from the other k bits forming the complementary subset to build the codeword by concatenation of the two subsets, provided the bits in the latter subset are linearly independent of each other. Fossorier-Lin algorithm uses this property to compute part of the least reliable bits forming a first subset of bits, from the other subset of linearly independent bits comprising more reliable bits. At least one bit of the second subset is inverted alternatively, forming a set of intermediate candidates. The matrix allowing computation of the bits of one subset from the bits of the other subset is known and based on algebraic linear computation. Then the known algebraic linear coding method is applied to the intermediate candidates to compute the other subset of bits. The second set of candidates is obtained by concatenating the complementary two subsets of bits. In order-1 Fossorier-Lin algorithm (FL-1), only one bit is alternatively inverted in the subset of more reliable bits. In order-2 Fossorier-Lin algorithm (FL-2), 2 bits are alternatively inverted. In accordance with a preferred embodiment of the invention, the process starts by inverting only one bit among the less reliable bits of the subset in the order of inverse reliability such as in FL-1 and continues by inverting two bits among the less reliable ones such as in FL-2, before completing the processing of FL-1. Then the Euclidian distance from the obtained modulated codewords or candidates to the received real sequence may be computed to select the best candidate among the second set of candidates.

The second error correction processing can be summarized as follows. The second set of candidates is derived after concatenating 2 complementary subsets of linearly independent bits. A subset of less reliable bits is computed from a subset of more reliable bits wherein some bits are alternatively changed using one or a combination of Fossorier-Lin variants, which involve a known linear coding method.

Selection means are provided to select one candidate from the first and the second set of candidates produced by the Chase or the Fossorier-Lin variants. The selection is made using a predetermined criterion which provides the possibility of deciding which candidate is the most reliable one. In the preferred embodiment of the invention, this criterion is based on the calculation of the Euclidian distance between each modulated candidate \check{e}ⱼ and the real received sequence rⱼ. This Euclidian distance, denoted d_{E}, is defined as follows:

$${d}_{E} = \sqrt{{\sum }_{j = 1}^{N} {( {\hat{e}}_{j} - {r}_{j} )}^{2}}$$

The most reliable candidate êⱼ, which will be selected in fine is the one, which minimizes the Euclidian distance.

If the used code is non-binary over GF(2^{m}), the invention provides means for transforming the non-binary code into a binary code by transforming the non-binary parity check matrix of the code, denoted H, into a binary matrix, denoted H_{bin}.

A non-binary linear block code of length n and dimension k is denoted C(n,k). The primitive polynomial of GF(2^{m}) is denoted P(x)=x^{m}+Pₘ₋₁ x^{m-1}+ . . . +P₀ and has a zero, denoted α. The decoding means comprise:
means for producing a binary sequence from the received data sequence,
means for applying a decoding algorithm to the binary sequence using a parity check matrix H_{bin}, wherein, compared to the parity check matrix H of the non binary linear block code C(n,k), the FIG. 0 is replaced by the matrix 0ₘ having m lines and m columns and all-zero elements, the FIG. 1 is replaced by the square identity matrix 0ₘ, having m lines and m columns, the figure α¹ is replaced by the matrix A¹, where the matrix A is the binary matrix equivalent to a defined as follows

$$A = [ \begin{matrix}{P}_{m - 1} & 1 & 0 & ⋯ & 0 \\ {P}_{m - 2} & 0 & 1 & ⋯ & 0 \\ ⋮ & & & & ⋮ \\ {P}_{1} & 0 & 0 & ⋯ & 1 \\ {P}_{0} & 0 & 0 & ⋯ & 0\end{matrix} ] .$$

For example, if C(n,k) is a classical (non-shortened) Reed-Solomon code, the binary representation of the parity check matrix of C is:

$${H}_{bin} = [ \begin{matrix}{I}_{m} & A & {A}^{2} & {A}^{3} & {A}^{4} & ⋯ & {A}^{n - 1} \\ {I}_{m} & {A}^{2} & {A}^{4 mod [ n ]} & {A}^{6 [ n ]} & {A}^{8 [ n ]} & ⋯ & {A}^{2 ( n - 1 ) [ n ]} \\ ⋯ & ⋯ & ⋯ & ⋯ & ⋯ & ⋯ & ⋯ \\ {I}_{m} & {A}^{n - k} & {A}^{2 ( n - k ) [ n ]} & {A}^{3 ( n - k ) [ n )} & {A}^{4 ( n - k )} & ⋯ & {A}^{( n - k ) ( n - 1 ) [ n ]}\end{matrix} ] .$$

If c is a symbol of the code and (c1, c2, . . . , cm)^{t} its binary vectorial representation, the polynomial x×c(x) corresponds to the product α×c and to the vectorial product A×(c1, c2, . . . cm)^{t}, the received sequence must be decomposed into a binary sequence. Then the Dorsch or Dual Fossorier-Lin algorithm as described in the articles by B. G. Dorsch: “a decoding algorithm for binary block codes and j-ary output channels” In IEEE Transactions on Information Theory, vol IT-20, pages 391-394, May 1974[3] or in the article by Fossorier-Lin [2], respectively, is performed on the n×m received sequence, using H_{bin}.

In another embodiment of the invention, a soft-input soft-output (SISO) complementary decoding is performed. In this embodiment, a soft-decision (SD) output is provided for each bit. The absolute value of the SD output corresponds to the reliability of the decision made on that bit by the soft-input decoder. For both Chase and Fossorier-Lin algorithms, SD is found using the method described in the article by M. P. C. Fossorier and S. Lin: “Soft-input soft-output decoding of linear block codes based on ordered statistics” In Proceedings of Globecom 98, pages 2828-2833, 1998 and in the article by R. M. Pyndiah “Near-optimum decoding of product codes: Block Turbo codes” In IEEE Transactions on Communications, vol 46, no 8, pages 1003-1010, August 1998. This method is described for binary codes and with Chase algorithm, but it can be extended to any method that produces a subset of codewords, as described in the article by P. Sweeney and S. Wesemeyer: Iterative soft-decision decoding of block codes, IEEE Proceedings, vol 147, pages 133-136, June 2000.

In accordance with this embodiment, the first decoding means process a Chase variant, the second decoding means process a Fossorier-Lin variant, and the selection means determine the best codeword candidate, which minimizes the Euclidian distance to the received sequence. If one algorithm falls to produce a candidate, its distance is set to a high fixed value. If the best candidate was produced by the Chase variant, the output is the soft-output given by the SISO Chase algorithm. If the best candidate was produced by the Fossorier-Lin variant, the output is the soft-output given by the SISO Fossorier-Lin algorithm. If both algorithms produced the same best candidate, then for each bit, two cases are distinguished:
1) if Chase algorithm output's absolute value is constant over all the first set of candidates (the Chase candidates), then the Fossorier-Lin SISO soft-output is chosen,
2) or else, the output of lowest absolute value is chosen.

FIG. 2 shows an optical system within which the invention can be implemented. It comprises a data source and a receiver. The data source is an optical disk 21 wherein digital encoded data are stored. The receiver is an optical reader for reading and decoding the encoded data stored on the optical disk. The reader comprises decoding means 23, as the one described with reference to FIG. 1, and optical reading means 24 to read the encoded data before decoding. The decoded data are then directed to an output 25 of the receiver or being treated.

The drawings and their description hereinbefore illustrate rather than limit the invention. It will be evident that there are numerous alternatives, which fall within the scope of the appended claims. In this respect, the following closing remarks are made.

There are numerous ways of implementing functions by means of items of hardware or software, or both. In this respect, the drawings are very diagrammatic, each representing only one possible embodiment of the invention. Thus, although a drawing shows different functions as different blocks, this by no means excludes that a single item of hardware or software carries out several functions. Nor does it exclude that an assembly of items of hardware or software, or both carries out a function.

Any reference sign in a claim should not be construed as limiting the claim. Use of the verb “to comprise” and its conjugations does not exclude the presence of elements or steps other than those stated in a claim. Use of the article “a” or “an” preceding an element or step does not exclude the presence of a plurality of such elements or steps.

1. A receiver for receiving a sequence of encoded data produced by a data source from an information sequence and encoded by an encoder, the received encoded data sequence possibly comprising errors, the receiver comprising decoding means for retrieving the information sequence from the received encoded data sequence, the decoding means comprising:
first decoding means using a first error correction algorithm for producing a first set of at least one candidate corresponding to a first selection of possible information sequence produced by the data source,
second decoding means using a second error correction algorithm for producing a second set of at least one candidate corresponding to a second selection of possible information sequence produced by the data source,
selection means for selecting, among the first and second set of candidates, the most reliable candidate with respect to a predetermined criterion.

2. A receiver as claimed in claim 1, wherein each data of the received data sequence comprises m bits, each bit having an associated reliability, the first decoding means comprising:
means for classifying the received data bits with respect to their reliabilities,
means for building a first set of intermediate candidates from the received data bits wherein part of the bits having the lower reliabilities are changed,
means for applying a predetermined hard decoding algorithm to the intermediate candidates for producing the first set of candidates.

3. A receiver as claimed in claim 1, wherein each data of the received data sequence comprises m bits, each bit having an associated reliability, the second decoding means comprising:
means for classifying the received data bits with respect to their reliabilities,
means for building a second set of intermediate candidates from the received data bits wherein part of the bits having the higher reliabilities are changed,
means for applying a predetermined coding algorithm to the intermediate candidates for producing the second set of candidates by re-calculating at least a part of least reliable bits from a set of most reliable bits, which are linearly independent of the other bits.

4. A receiver as claimed in claim 1, wherein the predetermined criterion used by the selection means is based on a distance between the received data and the candidates from the first and second set of candidates, the most reliable candidate being the candidate for which said distance with the received data is minimum.

5. A receiver as claimed in claims 2, 3 and 4, wherein the first and second decoding means produce soft outputs including the first and second set of candidates with reliabilities associated with the bits forming said candidates, and wherein the selection means comprise means for assigning a reliability, denoted the output reliability, to each bit of the selected most reliable candidate, which is based on the lowest value between the reliabilities produced by said first and second decoding means associated with said most reliable candidate if both decoding means produced said most reliable candidate or based on the reliability produced by either said first or said second decoding means if only one of said first and second decoding means produced said most reliable candidate.

6. A receiver as claimed in claim 4, wherein the distance between the received data and the candidates of the first and second set of candidates is the Euclidian distance.

7. A receiver for receiving an encoded data sequence produced by a data source from an information sequence using a non binary linear block code C(n,k) of length n, dimension k, the number of bits per encoded data being denoted m, and where the primitive polynomial of the Galois field is denoted P(x)=x^{m}+Pₘ₋₁ x^{m-1}+ . . . +P₀ having a zero denoted α, the received encoded data sequence possibly comprising errors, the receiver comprising decoding means for retrieving the information sequence from the received encoded data sequence, the decoding means comprising:
means for producing a binary sequence from the received data sequence,
means for applying a decoding algorithm to the binary sequence using a parity check matrix H_{bin}, wherein, compared to the parity check matrix H of the non-binary linear block code C(n,k), the Figure 0 is replaced by the matrix 0ₘ having m lines and m columns, the FIG. 1 is replaced by the square matrix Iₘ, having m lines and m columns, the figure α¹ is replaced by the matrix A¹, where the matrix A is the binary matrix equivalent to α defined as follows
$$A = [ \begin{matrix}{P}_{m - 1} & 1 & 0 & ⋯ & 0 \\ {P}_{m - 2} & 0 & 1 & ⋯ & 0 \\ ⋮ & & & & ⋮ \\ {P}_{1} & 0 & 0 & ⋯ & 1 \\ {P}_{0} & 0 & 0 & ⋯ & 0\end{matrix} ] .$$

8. A Method of receiving a sequence of encoded data produced by a data source from an information sequence, the received encoded data sequence possibly comprising errors, the method comprising a decoding step for retrieving the information sequence from the received encoded data sequence, the decoding step comprising:
a first decoding sub-step using a first error correction algorithm for producing a first set of at least one candidate corresponding to a first selection of possible information sequence produced by the data source,
a second decoding sub-step using a second error correction algorithm for producing a second set of at least one candidate corresponding to a second selection of possible information sequence produced by the data source,
a selection step for selecting, among the first and second set of candidates, the most reliable candidate with respect to a predetermined criterion.

9. A computer program product for a receiver computing a set of instructions, which when loaded into the receiver, causes the receiver to carry out the method as claimed in claim 7.

10. An Optical storage medium for storing encoded data produced by a data source from an information sequence, the stored encoded data sequence possibly comprising errors, wherein the encoded data are destined to be decoded by a receiver as claimed in claim 1.

11. A System comprising a data source and a receiver for receiving a sequence of encoded data produced by the data source from an information sequence, wherein the receiver is a receiver as claimed in claim 1.
